(19) United States
(12) Patent Application Publication
(10) Pub. No.: US 2026/0068442 A1
(43) Pub. Date: Mar. 5, 2026

(54) DISPLAY DEVICE

(71) Applicant: Magnolia White Corporation, Tokyo (JP)

(72) Inventors: Daichi HOSOKAWA, Tokyo (JP); Ryota TAKASAKI, Tokyo (JP); Sho YANAGISAWA, Tokyo (JP); Yozo NAKAYASU, Tokyo (JP); Hideyuki TAKAHASHI, Tokyo (JP); Masato NAKAMURA, Tokyo (JP)

(73) Assignee: Magnolia White Corporation, Tokyo (JP)

(21) Appl. No.: 19/318,448

(22) Filed: Sep. 4, 2025

(30) Foreign Application Priority Data
Sep. 4, 2024 (JP) 2024-152183

(51) Int. Cl. H10K 59/122; H10K 59/131; H10K 59/80

(52) U.S. Cl. CPC H10K 59/122; H10K 59/131; H10K 59/871

(57) ABSTRACT

According to one embodiment, a display device includes a substrate, an organic insulating layer provided across a display area and a surrounding area, an inorganic insulating layer provided across the display area and the surrounding area and covering the organic insulating layer, a lower electrode provided on the organic insulating layer and having a peripheral portion covered with the inorganic insulating layer in the display area, an organic layer provided on the lower electrode and including a light emitting layer, an upper electrode provided on the organic layer, and a first partition provided on the inorganic insulating layer, extending along an edge portion of the organic insulating layer in plan view, and overlapping the edge portion in the surrounding area.

### CROSS-REFERENCE TO RELATED APPLICATIONS

This application is based upon and claims the benefit of priority from Japanese Patent Application No. 2024-152183, filed Sep. 4, 2024, the entire contents of which are incorporated herein by reference.

### FIELD

Embodiments described herein relate generally to a display device.

### BACKGROUND

Recently, display devices with organic light-emitting diodes (OLED) applied thereto as display elements have been put into practical use. In this type of display devices, a technique for improving yields is required.

### BRIEF DESCRIPTION OF THE DRAWINGS

FIG. 1 is a view showing a configuration example of a display device DSP.

FIG. 2 is a diagram showing an example of the layout of subpixels SP1, SP2, and SP3 which constitute one pixel PX.

FIG. 3 is a schematic cross-sectional view of the display device DSP along the A-B line of FIG. 2.

FIG. 4 is a plan view showing an example of a mother substrate MS.

FIG. 5 is a schematic plan view of a panel portion PP.

FIG. 6 is a schematic plan view showing an area A near a cutting line CL2 shown in FIG. 5 in an enlarged manner.

FIG. 7 is a schematic cross-sectional view of the panel portion PP along the C-D line of FIG. 6.

FIG. 8 is a schematic plan view showing an area B near the cutting line CL2 shown in FIG. 5 in an enlarged manner.

FIG. 9 is a plan view showing a part of an edge portion 12E shown in FIG. 8 in an enlarged manner.

FIG. 10 is a schematic cross-sectional view of the panel portion PP along the E-F line of FIG. 9.

FIG. 11A is a view for explanations on a manufacturing method of the display device DSP.

FIG. 11B is a view for explanations on a manufacturing method of the display device DSP.

FIG. 11C is a view for explanations on a manufacturing method of the display device DSP.

FIG. 11D is a view for explanations on a manufacturing method of the display device DSP.

FIG. 11E is a view for explanations on a manufacturing method of the display device DSP.

FIG. 11F is a view for explanations on a manufacturing method of the display device DSP.

FIG. 12 is a schematic diagram showing a state where a stacked film FL1 is formed in a surrounding area SA of a panel portion PP.

FIG. 13 is a schematic diagram showing a state where the stacked film FL1 and a sealing layer SE11 are formed in the surrounding area SA of the panel portion PP.

FIG. 14 is a diagram for explaining another effect of the embodiment.

### DETAILED DESCRIPTION

An object of the embodiment is to provide a display device capable of improving yields.

In general, according to one embodiment, a display device includes a substrate, an organic insulating layer provided across a display area for displaying images and a surrounding area located further outward than the display area, an inorganic insulating layer provided across the display area and the surrounding area and covering the organic insulating layer, a lower electrode provided on the organic insulating layer and having a peripheral portion covered with the inorganic insulating layer in the display area, an organic layer provided on the lower electrode and including a light emitting layer, an upper electrode provided on the organic layer, and a first partition provided on the inorganic insulating layer, extending along an edge portion of the organic insulating layer in plan view, and overlapping the edge portion in the surrounding area.

According to another embodiment, a display device includes a substrate, a first inorganic insulating layer provided across a display area for displaying images and a surrounding area located further outward than the display area, a first wiring portion provided on the first inorganic insulating layer in the surrounding area, a second inorganic insulating layer covering the first wiring portion, a second wiring portion provided on the second inorganic insulating layer and electrically connected to the first wiring portion, a third inorganic insulating layer covering the second wiring portion, an organic insulating layer provided on the third inorganic insulating layer and having an edge portion directly above the first wiring portion, a fourth inorganic insulating layer covering the organic insulating layer and covering the third inorganic insulating layer in an area where the organic insulating layer is not provided, and a first partition provided on the fourth inorganic insulating layer and overlapping the edge portion in the surrounding area.

According to yet another embodiment, a display device includes a substrate, an organic insulating layer formed across a display area for displaying images and a surrounding area located further outward than the display area, an inorganic insulating layer provided across the display area and the surrounding area and covering the organic insulating layer, and a first partition provided on the inorganic insulating layer in the surrounding area. The organic insulating layer has an edge portion facing the display area. The edge portion includes a protrusion protruding toward the display area. The first partition overlaps the edge portion including the protrusion in plan view.

The present embodiment can provide a display device capable of improving yields.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as a first direction X. A direction parallel to the Y-axis is referred to as a second direction Y. A direction parallel to the Z-axis is referred to as a third direction Z. A plan view is defined as appearance when various types of elements are viewed parallel to the third direction Z. When terms indicating the positional relationships of two or more structural elements, such as “on”, “above” “between” and “face”, are used, the target structural elements may be directly in contact with each other or may be spaced apart from each other as a gap or another structural element is interposed between them. The positive direction of the Z-axis is referred to as an upward direction or a direction to an upper side.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

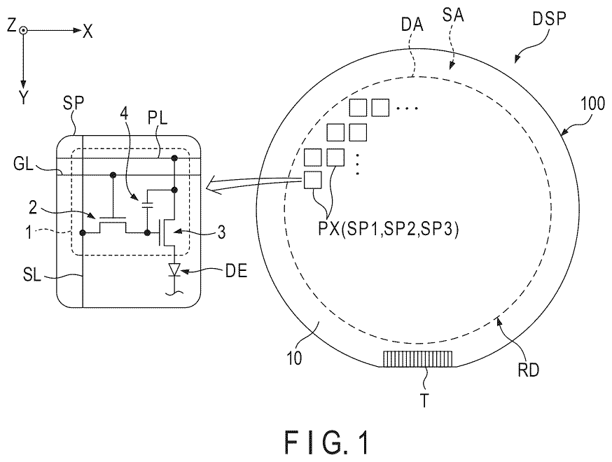

FIG. 1 is a view showing a configuration example of a display device DSP.

The display device DSP comprises a display panel 100. The display panel 100 has a display area DA for displaying an image and a surrounding area SA around the display area DA on an insulating substrate 10. The substrate 10 may be either a glass substrate or a resinous substrate having flexibility.

The outer edge of at least part of the display area DA has a round portion RD. In the illustrated example, the display area DA has a circular shape in plan view. The shape of the display area DA in plan view is not limited to the illustrated example. For example, the outer edge of the display area DA may be constituted by the combination of the round portion RD and a straight-line portion.

The display area DA comprises a plurality of pixels PX arranged in a matrix in the first direction X and the second direction Y. Each pixel PX includes a plurality of subpixels SP that display different colors. For example, each pixel PX includes a subpixel SP1, which displays the first color, a subpixel SP2, which displays the second color, and a subpixel SP3, which displays the third color. The first color, the second color, and the third color are different colors. Each pixel PX may include a subpixel SP, which displays another color such as white in addition to the subpixels SP1, SP2, and SP3 or instead of one of the subpixels SP1, SP2, and SP3.

The round portion RD in the display area DA is a shape in a macroscopic scale. In a microscopic scale, this shape is formed by providing a plurality of pixels PX in a stair step layout.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A gate electrode of the pixel switch 2 is connected to a scanning line GL. Either a source electrode or a drain electrode of the pixel switch 2 is connected to a signal line SL, and the other is connected to a gate electrode of the drive transistor 3 and the capacitor 4. In the drive transistor 3, one of a source electrode and a drain electrode is connected to a power line PL and the capacitor 4. The other is connected to a display element DE. In the illustrated example, the scanning line GL and the power line PL extend in the first direction X and the signal line SL extends in the second direction Y.

The configuration of the pixel circuit 1 is not limited to the example shown in the figure. For example, the pixel circuit 1 may comprise more thin-film transistors and capacitors.

For example, the display element DE is an organic light emitting diode (OLED) as a light emitting element and thus may be called an organic EL element.

The display device DSP further comprises a terminal portion T provided in the surrounding area SA. The terminal portion T comprises a plurality of terminals. For example, the terminal portion T is electrically connected to an IC chip or a flexible printed circuit board for driving the display elements DE.

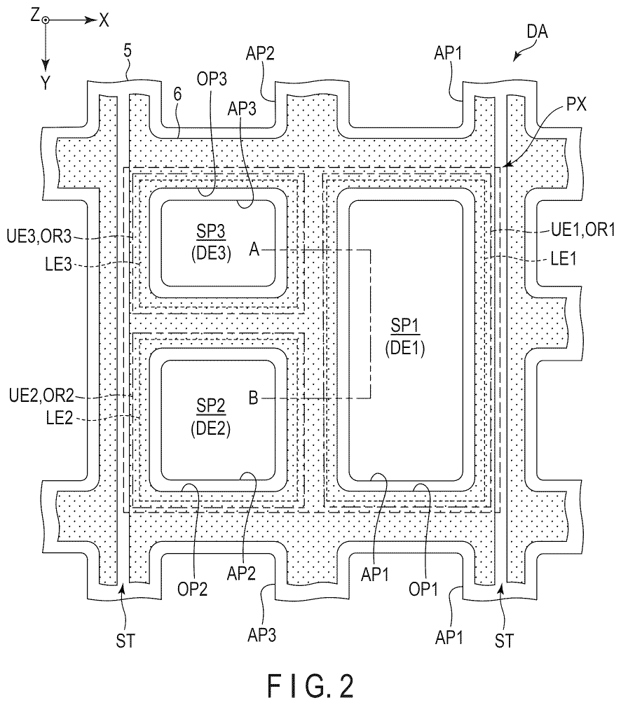

FIG. 2 is a diagram showing an example of the layout of the subpixels SP1, SP2, and SP3 which constitute one pixel PX.

In the illustrated example, the subpixels SP2 and SP3 are arranged in the second direction Y. The subpixels SP1 and SP2 are arranged in the first direction X. The subpixels SP1 and SP3 are arranged in the first direction X.

When the subpixels SP1, SP2, and SP3 are arranged in this layout, in the display area DA, a column in which the subpixels SP2 and SP3 are alternately arranged in the second direction Y and a column in which the plurality of subpixels SP1 are arranged in the second direction Y are formed. These columns are alternately arranged in the first direction X. The layout of the subpixels SP1, SP2, and SP3 is not limited to the example of FIG. 2.

An inorganic insulating layer 5 and a partition 6 are provided in the display area DA. The inorganic insulating layer 5 has apertures AP1, AP2, and AP3 in the respective subpixels SP1, SP2, and SP3. The inorganic insulating layer 5 having these apertures AP1, AP2, and AP3 may be called a rib.

The partition 6 overlaps the inorganic insulating layer 5 in plan view. The partition 6 is formed into a grating shape surrounding the apertures AP1, AP2, and AP3. In other words, the partition 6 has respective apertures OP1, OP2, and OP3 in the subpixels SP1, SP2, and SP3 in the same manner as the inorganic insulating layer 5. The aperture OP1 overlaps the aperture AP1. The aperture OP2 overlaps the aperture AP2. The aperture OP3 overlaps the aperture AP3. The partition 6 is conductive and is electrically connected to a terminal with common voltage at the terminal portion T shown in FIG. 1.

The subpixels SP1, SP2, and SP3 comprise the respective display elements DE1, DE2, and DE3 as the display elements DE.

The display element DE1 of the subpixel SP1 comprises a lower electrode LE1, an upper electrode UE1, and an organic layer OR1, which overlap the aperture AP1. The peripheral portion of the lower electrode LE1 is covered with the inorganic insulating layer 5. The lower electrode LE1, the organic layer OR1, and the upper electrode UE1, which constitute the display element DE1 are surrounded by the partition 6 in plan view. The peripheral portion of each of the organic layer OR1 and the upper electrode UE1 overlaps the inorganic insulating layer 5 in plan view.

The display element DE2 of the subpixel SP2 comprises a lower electrode LE2, an upper electrode UE2, and an organic layer OR2, which overlap the aperture AP2. The peripheral portion of the lower electrode LE2 is covered with the inorganic insulating layer 5. The lower electrode LE2, the organic layer OR2, and the upper electrode UE2, which constitute the display element DE2 are surrounded by the partition 6 in plan view. The peripheral portion of each of the organic layer OR2 and the upper electrode UE2 overlaps the inorganic insulating layer 5 in plan view.

The display element DE3 of the subpixel SP3 comprises a lower electrode LE3, an upper electrode UE3, and an organic layer OR3, which overlap the aperture AP3. The peripheral portion of the lower electrode LE3 is covered with the inorganic insulating layer 5. The lower electrode LE3, the organic layer OR3, and the upper electrode UE3, which constitute the display element DE3, are surrounded by the partition 6 in plan view. The peripheral portion of each of the organic layer OR3 and the upper electrode UE3 overlaps the inorganic insulating layer 5 in plan view.

In the illustrated example, the outlines of the lower electrodes LE1, LE2, and LE3 are indicated by dotted lines, and the outlines of the organic layers OR1, OR2, and OR3 and the upper electrodes UE1, UE2, and UE3 are indicated by one-dot chain line. The outer shape of each of the lower electrodes, organic layers and upper electrodes shown in the figure does not necessarily reflect the accurate shape.

For example, the lower electrodes LE1, LE2, and LE3 correspond to the anodes of the display elements. The upper electrodes UE1, UE2, and UE3 correspond to the cathodes of the display elements or a common electrode and contact the partition 6.

The lower electrode LE1 is electrically connected to the pixel circuit 1 (refer to FIG. 1) of the subpixel SP1. The lower electrode LE2 is electrically connected to the pixel circuit 1 of the subpixel SP2. The lower electrode LE3 is electrically connected to the pixel circuit 1 of the subpixel SP3.

In the illustrated example, the planar size of the aperture AP1, the planar size of the aperture AP2, and the planar size of the aperture AP3 differ from each other. The planar size of the aperture AP1 is greater than that of the aperture AP2. The planar size of the aperture AP2 is greater than that of the aperture AP3.

The partition 6 has a plurality of slits ST. In the illustrated example, each of the slits ST extends in the second direction Y. For example, the subpixels SP1, SP2, and SP3 constituting one pixel PX are provided between two slits ST adjacent to each other in the first direction X. The slit ST may be omitted.

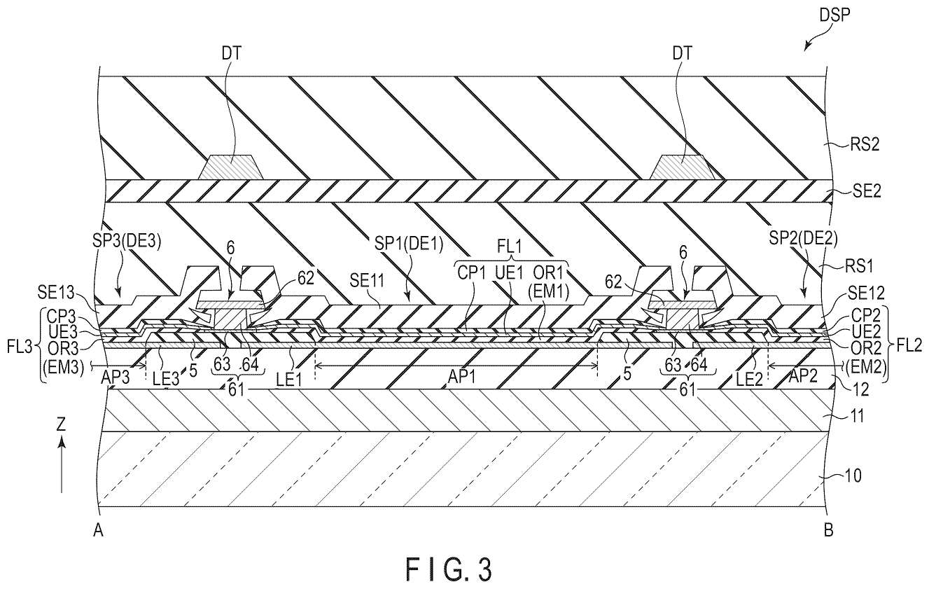

FIG. 3 is a schematic cross-sectional view of the display device DSP along the A-B line of FIG. 2.

A circuit layer 11 is provided on the substrate 10. The circuit layer 11 includes various circuits such as the pixel circuits 1 shown in FIG. 1, various lines such as the scanning lines GL, the signal lines SL, and the power lines PL, and various insulating layers.

The organic insulating layer 12 is provided on the circuit layer 11. For example, the organic insulating layer 12 is formed to planarize irregularities formed by the circuit layer 11.

The lower electrode LE1 of the subpixel SP1, the lower electrode LE2 of the subpixel SP2, and the lower electrode LE3 of the subpixel SP3 are provided on the organic insulating layer 12 and are spaced apart from each other.

The inorganic insulating layer 5 is provided on the organic insulating layer 12 and the lower electrodes LE1, LE2, and LE3. The aperture AP1 of the inorganic insulating layer 5 overlaps the lower electrode LE1. The aperture AP2 overlaps the lower electrode LE2. The aperture AP3 overlaps the lower electrode LE3. The peripheral portions of the lower electrodes LE1, LE2, and LE3 are covered with the inorganic insulating layer 5. The lower electrodes LE1, LE2, and LE3 are connected to the pixel circuits 1 of the respective subpixels SP1, SP2, and SP3 through the contact hole provided in the organic insulating layer 12. FIG. 3 omits the illustration of the contact hole in the organic insulating layer 12.

The partition 6 has a conductive lower portion 61 provided on the inorganic insulating layer 5 and an upper portion 62 provided on the lower portion 61.

In the illustrated example, the lower portion 61 has a bottom layer 63 provided on the inorganic insulating layer 5 and a stem layer 64 provided between the bottom layer 63 and the upper portion 62. The bottom layer 63 is thinner than the stem layer 64. The bottom layer 63 has the width greater than that of the stem layer 64. The both end portions of the bottom layer 63 protrude relative to the side surfaces of the stem layer 64.

The upper portion 62 is provided on the stem layer 64. The upper portion 62 has the width greater than that of the stem layer 64. The both end portions of the upper portion 62 protrude relative to the side surfaces of the stem layer 64. In the present specification, the side surfaces of the stem layer 64 are assumed to be the side surfaces of the stem layer 64 that extend between the bottom layer 63 and the upper portion 62. In the illustrated example, the upper portion 62 has the width greater than that of the bottom layer 63. The bottom layer 63 may have a width greater than that of the upper portion 62.

In the display element DE1, the organic layer OR1 contacts the lower electrode LE1 through the aperture AP1 and covers the lower electrode LE1 exposed from the aperture AP1. The peripheral portion of the organic layer OR1 is located on the inorganic insulating layer 5. The upper electrode UE1 covers the organic layer OR1 and contacts the lower portion 61.

In the display element DE2, the organic layer OR2 contacts the lower electrode LE2 through the aperture AP2 and covers the lower electrode LE2 exposed from the aperture AP2. The peripheral portion of the organic layer OR2 is located on the inorganic insulating layer 5. The upper electrode UE2 covers the organic layer OR2 and contacts the lower portion 61.

In the display element DE3, the organic layer OR3 contacts the lower electrode LE3 through the aperture AP3 and covers the lower electrode LE3 exposed from the aperture AP3. The peripheral portion of the organic layer OR3 is located on the inorganic insulating layer 5. The upper electrode UE3 covers the organic layer OR3 and contacts the lower portion 61.

The contact between each of the upper electrodes UE1, UE2, and UE3 and the lower portion 61 includes a case where each of the upper electrodes UE1, UE2, and UE3 directly contacts the upper surface of the bottom layer 63 and a case where each of the upper electrodes UE1, UE2, and UE3 directly contacts the upper surface of the bottom layer 63 and further directly contacts the side surfaces of the stem layer 64. In this specification, the upper surface of the bottom layer 63 is assumed to have, of the bottom layer 63, the surface that directly contacts the stem layer 64 and the surface that protrudes relative to the stem layer 64 and faces the upper portion 62.

In the illustrated example, the subpixel SP1 has the cap layer CP1 and a sealing layer SE11. The subpixel SP2 has the cap layer CP2 and a sealing layer SE12. The subpixel SP3 has the cap layer CP3 and a sealing layer SE13. The cap layers CP1, CP2 and CP3 function as optical adjustment layers, which improve the extraction efficiency of light emitted from the organic layers OR1, OR2, and OR3, respectively. The cap layers CP1, CP2, and CP3 may be omitted.

The cap layer CP1 is provided on the upper electrode UE1. The cap layer CP2 is provided on the upper electrode UE2. The cap layer CP3 is provided on the upper electrode UE3.

The sealing layer SE11 is provided on the cap layer CP1, contacts the partition 6, and continuously covers each member of the subpixel SP1. The sealing layer SE11 contacts the stem layer 64 and the upper portion 62 of the partition 6 that surrounds the display element DE1.

The sealing layer SE12 is provided on the cap layer CP2, contacts the partition 6, and continuously covers each member of the subpixel SP2. The sealing layer SE12 contacts the stem layer 64 and the upper portion 62 of the partition 6 that surrounds the display element DE2.

The sealing layer SE13 is provided on the cap layer CP3, contacts the partition 6, and continuously covers each member of the subpixel SP3. The sealing layer SE13 contacts the stem layer 64 and the upper portion 62 of the partition 6 that surrounds the display element DE3.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

The end portions of the sealing layers SE11, SE12 and SE13 are located on the partition 6. In the illustrated example, the sealing layer SE11 located on the partition 6 between the subpixels SP1 and SP2 is spaced apart from the sealing layer SE12 located on this partition 6. Further, the sealing layer SE11 located on the partition 6 between the subpixels SP1 and SP3 is spaced apart from the sealing layer SE13 located on this partition 6.

The stacked films FL1, FL2, and FL3 are not formed on the partition 6. Gaps are formed between the sealing layer SE11 and the partition 6, between the sealing layer SE12 and the partition 6, and between the sealing layer SE13 and the partition 6.

The transparent resin layer RS1 covers the partition 6 and the sealing layers SE11, SE12, and SE13. Further, the resin layer RS1 is filled into the gap formed on the partition 6.

The sealing layer SE2 covers the resin layer RS1. A transparent resin layer RS2 covers the sealing layer SE2.

A detection electrode DT for achieving a touch sensor function of detecting contact or approach of an object to the display area DA is provided on the sealing layer SE2 and is covered with the resin layer RS2. For example, the detection electrode DT is a multilayer body having an aluminum layer formed of an aluminum-based material and a titanium layer formed of a titanium-based material. The touch sensor function is implemented by detecting a capacity variation in the sensor modules constituted by the detection electrode DT.

Each of the inorganic insulating layer 5, the sealing layers SE11, SE12, and SE13 and the sealing layer SE2 is formed of, for example, an inorganic insulating material such as a silicon nitride (SiNx), a silicon oxide (SiOx), a silicon oxynitride (SiON) or an aluminum oxide (Al₂O₃). For example, the inorganic insulating layer 5 is formed of a silicon oxynitride, and each of the sealing layers SE11, SE12, SE13, and SE2 is formed of a silicon nitride.

The lower portion 61 of the partition 6 is formed of a conductive material and is electrically connected to the upper electrodes UE1, UE2, and UE3.

The bottom layer 63 is formed of, for example, a titanium-based material such as titanium or a titanium compound. The stem layer 64 is formed of a material different from those of the bottom layer 63 and the upper portion 62, and is formed of, for example, an aluminum-based material such as aluminum or an aluminum compound.

The upper portion 62 of the partition 6 is formed of, for example, a conductive material. However, the upper portion 62 may be formed of an insulating material. The upper portion 62 is formed of a material different from that of the lower portion 61. For example, the upper portion 62 is formed of a titanium-based material such as titanium or a titanium compound or an oxide conductive material such as an indium tin oxide (ITO).

Each of the lower electrodes LE1, LE2, and LE3 is, for example, a multilayer body having a transparent layer formed of an oxide conductive material such as an indium tin oxide (ITO) and a reflective layer formed of a metal material such as silver. For example, each of the lower electrodes LE1, LE2, and LE3 is a multilayer body having a reflective layer between a pair of transparent layers.

The organic layer OR1 has a light emitting layer EM1. The organic layer OR2 has a light emitting layer EM2. The organic layer OR3 has a light emitting layer EM3. The light emitting layers EM1, EM2, and EM3 are formed of materials different from each other. For example, the light emitting layer EM1 is formed of a material that emits light in a blue wavelength range. The light emitting layer EM2 is formed of a material that emits light in a green wavelength range. The light emitting layer EM3 is formed of a material that emits light in a red wavelength range. The light emitting layer EM1 may be formed of a material that emits light in a green wavelength. The light emitting layer EM2 may be formed of a material that emits light in a blue wavelength.

Each of the organic layers OR1, OR2, and OR3 has a plurality of functional layers such as a hole injection layer, a hole transport layer, an electron blocking layer, a hole blocking layer, an electron transport layer, and an electron injection layer.

The upper electrodes UE1, UE2, and UE3 are formed of, for example, a metal material such as an alloy of magnesium and silver (MgAg).

Each of the cap layers CP1, CP2, and CP3 is a multilayer body consisting of a plurality of thin films. All of the thin films are transparent and have refractive indices different from each other.

The circuit layer 11, the organic insulating layer 12, and the inorganic insulating layer 5, which are illustrated, are provided across the display area DA and the surrounding area SA.

Now, this specification describes a mother substrate MS for a display device (hereinafter, simply referred to as a mother substrate) for manufacturing a plurality of display devices DSP collectively.

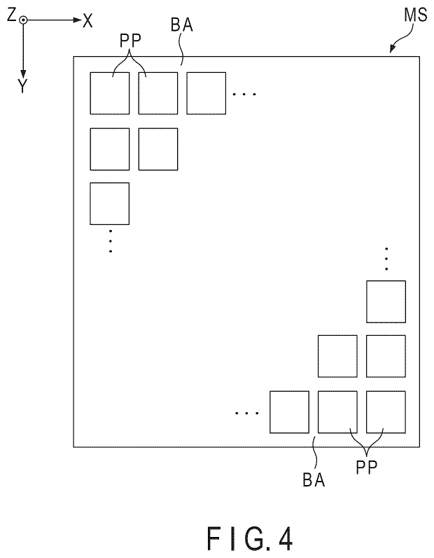

FIG. 4 is a plan view showing an example of the mother substrate MS.

For example, the mother substrate MS has a rectangular shape as shown in the figure. However, the mother substrate MS may have another shape such as a circular shape. The mother substrate MS comprises a plurality of panel portions PP provided in a matrix and a margin portion BA around these panel portions PP. In the example of FIG. 4, the plurality of panel portions PP are arranged in the first direction X and the second direction Y via the margin portion BA. The layout of the panel portions PP in the mother substrate MS is not limited to this example. As another example, some of the panel portions PP may be arranged without interposing the margin portion BA therebetween.

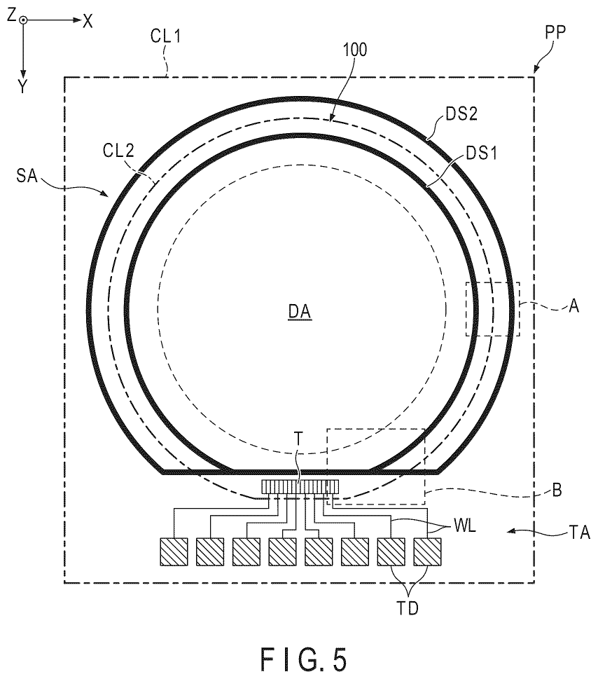

FIG. 5 is a schematic plan view of the panel portion PP.

The outer shape of the panel portion PP corresponds to a cutting line CL1 for cutting out each panel portion PP from the mother substrate MS.

Each panel portion PP has the display area DA and the surrounding area SA. The surrounding area SA in the panel portion PP corresponds to the area between the display area DA and the cutting line CL1.

The surrounding area SA further has a cutting line CL2, which is the outer shape of the substrate 10 of the display panel 100 shown in FIG. 1. The surrounding area SA includes an inspection area TA between the cutting lines CL1 and CL2. The inspection area TA comprises a plurality of inspection pads TD for inspecting the operation of the display device DSP. Each of the inspection pads TD is electrically connected to the terminal portion T via a wire WL.

The cutting line CL2 is located between the terminal portion T and each of the inspection pads TD in the vicinity of the terminal portion T. That is, the cutting line CL2 intersects the plurality of wires WL.

In the manufacturing of the display device DSP, the mother substrate MS shown in FIG. 4 is cut along the cutting line CL1 and the panel portions PP are cut out from the mother substrate MS. Then, this cut-out panel portion PP is subjected to the inspection using the inspection pad TD. After this inspection, the panel portion PP is cut along the cutting line CL2, the display panel 100 is cut out from the panel portion PP, and the inspection area TA is cut out from the display panel 100.

The panel portion PP comprises dam structures DS1 and DS2. The dam structure DS1 is located between the cutting line CL2 and the display area DA and is formed in a ring shape surrounding the display area DA. The dam structure DS2 is located between the cutting lines CL1 and CL2 and is formed in a ring shape surrounding the dam structure DS1. In the illustrated example, the dam structure DS2 intersects the cutting line CL2 in the vicinity of the terminal portion T and is coupled with the dam structure DS1. The coupling portion of the dam structures DS1 and DS2 is provided between the terminal portion T and the display area DA.

The most part of the cutting line CL2 is located between the dam structures DS1 and DS2. In the illustrated example, the cutting line CL2 is located outside the dam structures DS1 and DS2 in the vicinity of the terminal portion T. That is, the cutting line CL2 intersects the dam structure DS2 in the vicinity of the terminal portion T.

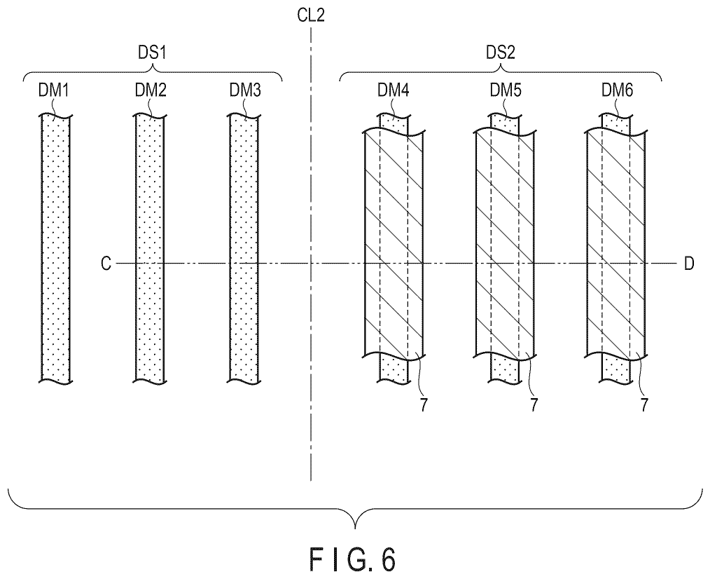

FIG. 6 is a schematic plan view showing an area A near the cutting line CL2 shown in FIG. 5 in an enlarged manner.

The dam structure DS1 comprises three dam portions DM1, DM2, and DM3. The dam structure DS2 comprises three dam portions DM4, DM5, and DM6. The number of dam portions that each of the dam structures DS1 and DS2 comprises is not limited to three. The cutting line CL2 is located between the dam portions DM3 and DM4.

A plurality of partitions 7 are provided in the area A. FIG. 6 shows some of them alone. For example, the partition 7 overlaps the dam portions DM4, DM5, and DM6 in plan view.

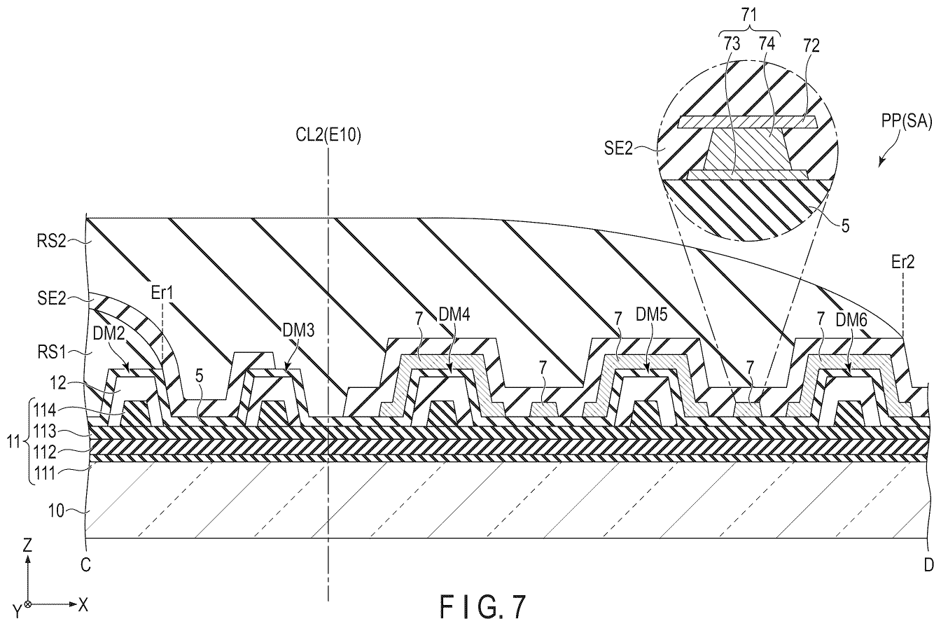

FIG. 7 is a schematic cross-sectional view of the panel portion PP along the C-D line of FIG. 6.

As shown in enlarged manner, the partition 7 is formed in the same manner as the partition 6 shown in FIG. 3. That is, the partition 7 comprises a lower portion 71 including a bottom layer 73 and a stem layer 64 that are provided on the inorganic insulating layer 5 and an upper portion 72 provided on the lower portion 71. In the partition 7 as well, both end portions of the upper portion 72 and both end portions of the bottom layer 73 protrude relative to the side surfaces of the stem layer 74.

The circuit layer 11 comprises an inorganic insulating layer 111 provided on the substrate 10, an inorganic insulating layer 112 provided on the inorganic insulating layer 111, an inorganic insulating layer 113 provided on the insulating layer 112, and an organic insulating layer 114 provided on the insulating layer 113. Though not illustrated in FIG. 7, the circuit layer 11 comprises a metal layer and a semiconductor layer provided between these insulating layers.

The inorganic insulating layers 111, 112, and 113 are formed of an inorganic insulating material such as a silicon nitride, a silicon oxide, or a silicon oxynitride. The organic insulating layer 12 covers the organic insulating layer 114.

For example, each of the dam portions DM2, DM3, DM4, DM5, and DM6 in the figure is formed as a stacked layer body of the organic insulating layers 114 and 12. The dam portion DM1 (not shown) is formed in the same manner as the dam portion DM2. Each of these dam portions is provided on the insulating layer 113 and is covered with the inorganic insulating layer 5. Each of the partitions 7 is provided on the inorganic insulating layer 5.

The dam portions DM1 and DM2 function to dam up the resin layer RS1 that is uncured. The dam portions DM3, DM4, DM5, and DM6 function to dam up the resin layer RS2 that is uncured. In the illustrated example, an end portion Er1 of the resin layer RS1 is located above the dam portion DM2. Further, an end portion Er2 of the resin layer RS2 is located above the dam portion DM6. The position of each of the end portions Er1 and Er2 is not limited to the illustrated example.

The sealing layer SE2 covers the resin layer RS1 and covers the inorganic insulating layer 5 and the partition 7 at the position extending further than the end portion Er1.

When the panel portion PP is cut along the cutting line CL2, the portion overlapping the cutting line CL2 of the substrate 10 corresponds to an outer edge E10 of the substrate 10. That is, in the display device DSP after being cut along the cutting line CL2, the sealing layer SE2 covers the inorganic insulating layer 5 in an area between the end portion Er1 of the resin layer RS1 and the outer edge E10 of the substrate 10.

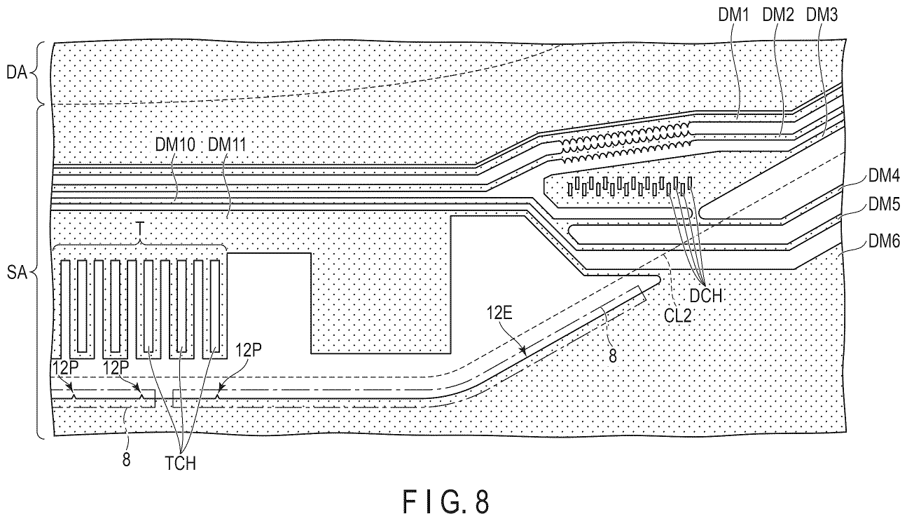

FIG. 8 is a schematic plan view showing an area B near the cutting line CL2 shown in FIG. 5 in an enlarged manner.

FIG. 8 mainly shows the pattern of the organic insulating layer 12 covering the organic insulating layer 114. Each of the dam portions DM1 and DM2 surrounds the display area DA. The dam portions DM4 and DM5 intersect the cutting line CL2, are coupled to the dam portion DM3, and form a dam portion DM10 corresponding to the coupling portion shown in FIG. 5. A portion of the dam portion DM6 is split. This split portion intersects the cutting line CL2 and constitutes the dam portion DM11. Each of the dam portions DM1, DM2, DM10, and DM11 is provided between the terminal portion T and the display area DA.

In the terminal portion T, a plurality of contact holes TCH for connecting the IC chip, the flexible printed circuit board, and the like to each other are formed. In the dam portion DM3, a plurality of contact holes DCH for the connection of the detection electrode DT are formed.

A partition 8 shown by one-dot chain lines in the figure extends along an edge portion 12E of the organic insulating layer 12, which is part of the dam portion DM6, and overlaps the edge portion 12E. The edge portion 12E overlapping the partition 8 faces the display area DA of the organic insulating layer 12. The edge portion 12E has a protrusion 12P protruding toward the display area DA or the terminal portion T. The partition 8 overlaps the protrusion 12P as well.

When the partition 8 extends in a direction orthogonal to the direction of application of a resist to be described later, the partition 8 is preferably divided into a plurality of segments and space is preferably provided between adjacent segments to promote the spread of the resist.

The cutting line CL2 is located between the display area DA and the partition 8 and is located between the terminal portion T and the partition 8. In this case, the partition 8 is not provided in the display device DSP cut along the cutting line CL2. The partition 8 may be provided between the cutting line CL2 and the display area DA. In that case, the partition 8 is not provided in the display device DSP cut along the cutting line CL2.

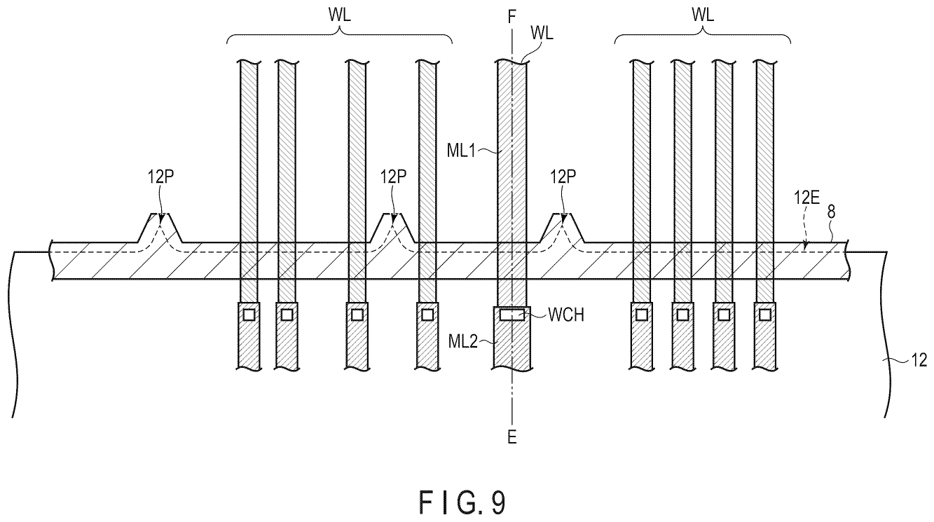

FIG. 9 is a plan view showing a part of the edge portion 12E shown in FIG. 8 in an enlarged manner.

As described with reference to FIG. 5, the illustrated wires WL electrically connect the inspection pads TD and the terminal portion T to each other. The plurality of wires WL intersect the edge portion 12E. Each of the wires WL comprises a wiring portion ML1 and a wiring portion ML2.

For example, the wiring portion ML1 is electrically connected to the terminal portion T, located in the same layer as the scanning line GL, and formed of the same material as the scanning line GL. The wiring portion ML1 intersects the edge portion 12E. For example, the wiring portion ML2 is electrically connected to the inspection pad TD, located in the same layer as the signal line SL, and formed of the same material as the signal line SL. Further, the wiring portions ML1 and ML2 are electrically connected to each other via a contact hole WCH.

The protrusion 12P of the edge portion 12E is located between adjacent wires WL. The partition 8 overlaps the edge portion 12E of the protrusion 12P. The wire WL intersects the partition 8.

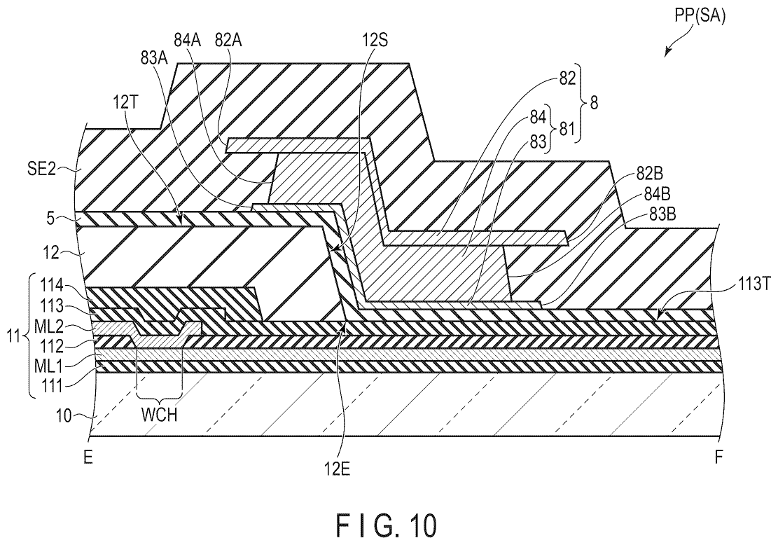

FIG. 10 is a schematic cross-sectional view of the panel portion PP along the E-F line of FIG. 9.

The circuit layer 11 comprises the wiring portions ML1 and ML2 in addition to the inorganic insulating layers 111, 112, and 113 and the organic insulating layer 114.

The wiring portion ML1 is provided on the inorganic insulating layer 111. The inorganic insulating layer 112 covers the wiring portion ML1 and the inorganic insulating layer 111. The wiring portion ML2 is provided on the inorganic insulating layer 112. The wiring portion ML2 contacts the wiring portion ML1 in the contact hole WCH formed in the inorganic insulating layer 112. The inorganic insulating layer 113 covers the wiring portion ML2 and the inorganic insulating layer 112.

The organic insulating layer 114 is provided on the inorganic insulating layer 113. The organic insulating layer 12 covers the organic insulating layer 114. A portion of the inorganic insulating layer 113 is exposed from the organic insulating layer 12. The organic insulating layer 12 has an upper surface 12T, which is substantially flat, and a side surface 12S inclined with respect to the upper surface 12T. The edge portion 12E of the organic insulating layer 12 corresponds to the intersection portion of the side surface 12S and an upper surface 113T of the inorganic insulating layer 113. In the illustrated cross section, the edge portion 12E is located directly above the wiring portion ML1.

The inorganic insulating layer 5 covers the organic insulating layer 12. In the area where the organic insulating layer 12 is not provided, the inorganic insulating layer 5 covers the inorganic insulating layer 113. That is, the inorganic insulating layer 5 contacts the upper surface 12T, the side surface 12S, and the upper surface 113T.

The partition 8 is provided on the inorganic insulating layer 5. The partition 8 comprises a lower portion 81 provided on the inorganic insulating layer 5 and an upper portion 82 provided on the lower portion 81. The lower portion 81 has a bottom layer 83 provided on the inorganic insulating layer 5, and a stem layer 84 provided on the bottom layer 83. The upper portion 82 is provided on the stem layer 84. Both end portions of the upper portion 82 protrude relative to the side surfaces of the lower portion 81 (or the side surfaces of the stem layer 84). Further, both end portions of the bottom layer 83 protrude relative to the side surfaces of the stem layer 84.

The partition 8 overlaps the edge portion 12E. That is, each of the bottom layer 83, the stem layer 84, and the upper portion 82 is located directly above the upper surface 12T and the side surfaces 12S of the organic insulating layer 12. In the area where the organic insulating layer 12 is not provided, each of the bottom layer 83, the stem layer 84, and the upper portion 82 is located directly above the upper surface 113T.

Each of the bottom layer 83 and the upper portion 82 has one end portion 83A and one end portion 82A that protrude relative to one side surface 84A of the stem layer 84 in the area overlapping the organic insulating layer 12. Each of the bottom layer 83 and the upper portion 82 further has the other end portion 83B and the other end portion 82B that protrude relative to the other side surface 84B of the stem layer 84 in the area where the organic insulating layer 12 is not provided.

The sealing layer SE2 covers the inorganic insulating layer 5 and the partition 8. In the partition 8, the both end portions 83A and 83B of the bottom layer 83 are covered with the sealing layer SE2, the both side surfaces 84A and 84B of the stem layer 84 are covered with the sealing layer SE2, and the upper portion 82 is also covered with the sealing layer SE2. Further, the sealing layer SE2 is filled into the gap between the bottom layer 83 and the upper portion 82. This mitigates irregularities caused by the partition 8.

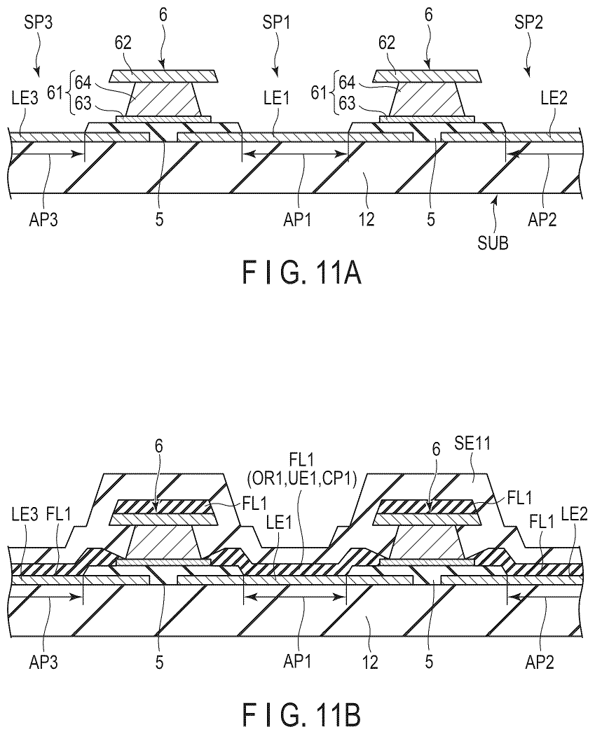

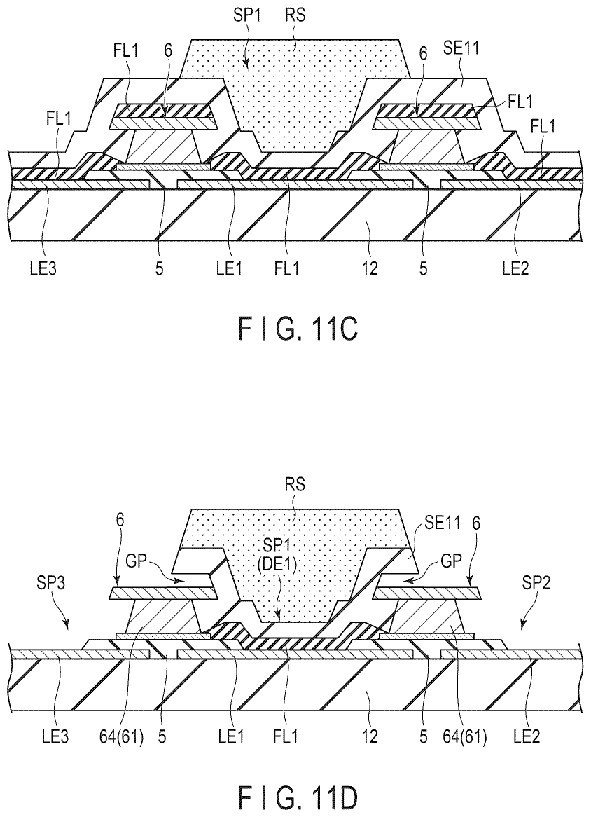

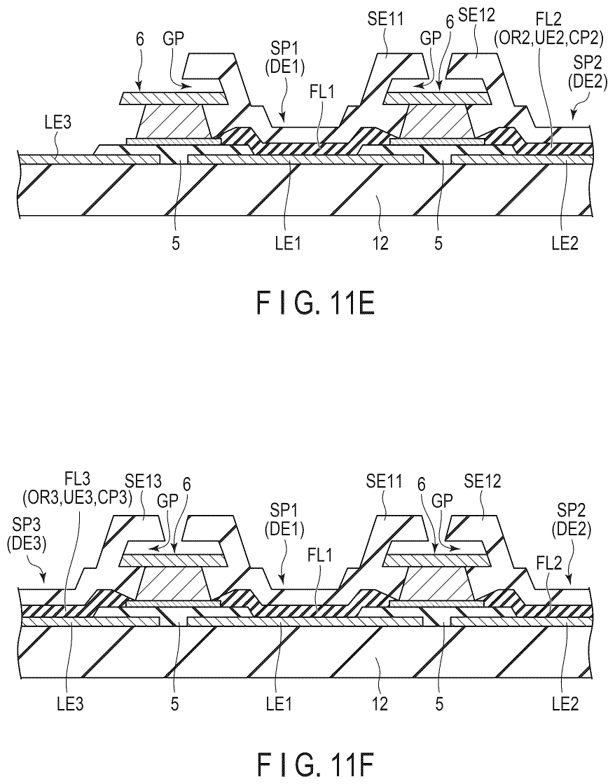

Next, the following describes a manufacturing method of the display device DSP. FIG. 11A to FIG. 11F omit the elements below the organic insulating layer 12.

First, a processing substrate SUB is prepared as shown in FIG. 11A. organic insulating layer 5 The process of preparing the processing substrate SUB includes the process of forming the lower electrode LE1 of the subpixel SP1, the lower electrode LE2 of the subpixel SP2, and the lower electrode LE3 of the subpixel SP3 on the organic insulating layer 12, the process of forming the inorganic insulating layer 5 having the apertures AP1, AP2, and AP3 overlapping the respective lower electrodes LE1, LE2, and LE3, and the process of forming the partition 6 having the lower portion 61 located on the inorganic insulating layer 5 and the upper portion 62 located on the lower portion 61. The partition 6 may be formed after the formation of the inorganic insulating layer 5 having the apertures AP1, AP2, and AP3. Alternatively, the apertures AP1, AP2, and AP3 may be formed in the inorganic insulating layer 5 after the formation of the partition 6.

Subsequently, the display element DE1 is formed.

First, the stacked film FL1 is formed on the processing substrate SUB by performing vapor deposition using the partition 6 as a mask as shown in FIG. 11B.

The stacked film FL1 includes the organic layer OR1 including the light emitting layer EM1, the upper electrode UE1, and the cap layer CP1. The organic layer OR1, the upper electrode UE1, and the cap layer CP1 are successively formed by an evaporation device in a vacuum state. The stacked film FL1 is divided by the partition 6 having an overhang shape.

Subsequently, the sealing layer SE11 continuously covering the stacked film FL1 and the partition 6 is formed. The sealing layer SE11 is formed by depositing inorganic insulating materials (for example, a silicon nitride) on the processing substrate SUB in a Chemical Vapor Deposition (CVD) device.

The stacked film FL1 and the sealing layer SE11 are substantially formed in the entire processing substrate SUB and are provided in the subpixels SP2 and SP3 as well as the subpixel SP1 in the display area DA.

Subsequently, a resist RS patterned into a predetermined shape is formed on the sealing layer SE11 as shown in FIG. 11C. The resist RS overlaps the subpixel SP1 and part of the partition 6 around the subpixel SP1.

Next, patterning is performed on the sealing layer SE11 and the stacked film FL1 using the resist RS as a mask as shown in FIG. 11D. After removing the sealing layer SE11 exposed from the resist RS by performing various etching using the resist RS as a mask, the cap layer CP1, the upper electrode UE1, and the organic layer OR1 included in the stacked film FL1 are removed in series.

These patterning processes make the lower electrode LE2 of the subpixel SP2 and the lower electrode LE3 of the subpixel SP3 exposed.

Subsequently, the resist RS is removed. This process forms the display element DE1 in the subpixel SP1. Further, in the illustrated example, the stacked film FL1 stacked on the partition 6 is removed in the processes between the patterning of the stacked film FL1 and the removal of the resist RS. Thus, a gap GP is formed between the sealing layer SE11 and the partition 6.

Subsequently, the display element DE2 is formed as shown in FIG. 11E. The procedure of forming the display element DE2 is the same as that of forming the display element DE1. That is, the stacked film FL2 is formed on the lower electrode LE2. The stacked film FL2 includes the organic layer OR2 having the light emitting layer EM2, the upper electrode UE2, and the cap layer CP2. Subsequently, the sealing layer SE12 is formed on the stacked film FL2. Subsequently, a resist is formed on the sealing layer SE12. Subsequently, patterning is performed using the resist as a mask. This sequentially removes the sealing layer SE12 and the stacked film FL2 exposed from the resist. Subsequently, the resist is removed.

This process forms the display element DE2 in the subpixel SP2 and makes the lower electrode LE3 of the subpixel SP3 exposed. In the illustrated example, the stacked film FL2 on the partition 6 is removed at the time of patterning. This forms the gap GP between the sealing layer SE12 and the partition 6.

Next, the display element DE3 is formed as shown in FIG. 11F. The procedure of forming the display element DE3 is the same as that of forming the display element DE1. That is, the stacked film FL3 is formed on the lower electrode LE3. The stacked film FL3 includes the organic layer OR3 having the light emitting layer EM3, the upper electrode UE3, and the cap layer CP3. Subsequently, the sealing layer SE13 is formed on the stacked film FL3. Subsequently, a resist is formed on the sealing layer SE13. Subsequently, patterning is performed using the resist as a mask. This sequentially removes the sealing layer SE13 and the stacked film FL3 exposed from the resist. Subsequently, the resist is removed.

This process forms the display element DE3 in the subpixel SP3. In the illustrated example, the stacked film FL3 on the partition 6 is removed at the time of patterning. This forms the gap GP between the sealing layer SE13 and the partition 6.

The above-described manufacturing process assumes a case where the display element DE1 is formed firstly, and the display element DE2 is formed secondly, and the display element DE3 is formed lastly. However, the formation order of the display elements DE1, DE2, and DE3 is not limited to this example.

Then, the resin layer RS1 is formed by applying a resin material. Then, the sealing layer SE2 is formed by stacking an inorganic insulating material. Then, a metal layer is formed on the sealing layer SE2 and patterned to form the detection electrode DT. Then, the resin layer RS2 is formed by applying a resin material.

Then, the mother substrate MS is cut along the cutting line CL1 and the panel portions PP are cut out. Then, the inspection process using the inspection pad TD is performed. Then, the panel portion PP is cut along the cutting line CL2 and the display panel 100 is cut out.

After these processes, an IC chip or a flexible printed circuit board is mounted on the terminal portion T, and the display device DSP is completed.

In the above manufacturing process, the stacked film FL1, the sealing layer SE11, the stacked film FL2, the sealing layer SE12, the stacked film FL3, and the sealing layer SE13 are formed in the surrounding area SA as well. For example, if the stacked film FL1 and the sealing layer SE11 are stripped from the processing substrate SUB before the patterning process described with reference to FIG. 11D, these detached films and layers could be a contaminant source in the manufacturing facility. Of the processing substrate SUB, the area from which the stacked film FL1 and the sealing layer SE11 are stripped could be damaged at the time of patterning. Thus, it is important to suppress undesirable stripping of the stacked film FL1 and the sealing layer SE11 in the surrounding area SA. Similarly, it is required to suppress undesirable stripping of the stacked film FL2 and the sealing layer SE12 and the stacked film FL3 and the sealing layer SE13.

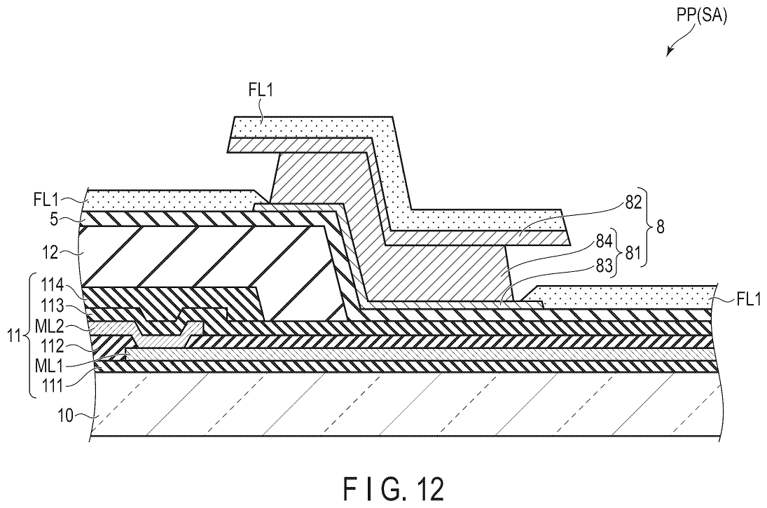

FIG. 12 is a schematic diagram showing a state where the stacked film FL1 is formed in the surrounding area SA of the panel portion PP.

In the area where the organic insulating layer 12 is provided and in the area where the organic insulating layer 12 is not provided, the stacked film FL1 is provided on the inorganic insulating layer 5. Further, in the area where the partition 8 overlapping the edge portion 12E is provided, the stacked film FL1 is provided on the partition 8. The portion provided on the partition 8 of the stacked film FL1 is spaced apart from the portion provided on the insulating layer 5 of the stacked film FL1. That is, when the stacked film FL1 is formed in the surrounding area SA, the stacked film FL1 is divided by the partition 8. Thus, the stacked film FL1 that has a great planar size is not formed. Thus, the stripping of the stacked film FL1 is suppressed even when pressure is applied to the stacked film FL1.

In the same manner, when the stacked film FL2 is formed in the surrounding area SA as well, the stacked film FL2 is divided by the partition 8. In the same manner, when the stacked film FL3 is formed in the surrounding area SA as well, the stacked film FL3 is divided by the partition 8. This suppresses undesirable stripping of the stacked film FL2 and the stacked film FL3.

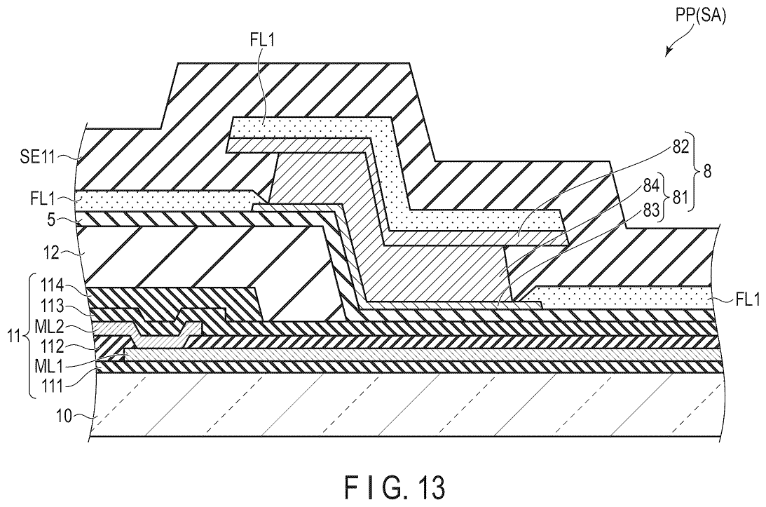

FIG. 13 is a schematic diagram showing a state where the stacked film FL1 and the sealing layer SE11 are formed in the surrounding area SA of the panel portion PP.

The sealing layer SE11 is provided on the divided stacked film FL1 and covers the stacked film FL1 with the partition 8. This suppresses undesirable stripping of the stacked film FL1 and the sealing layer SE11.

Similarly, when the stacked film FL2 and the sealing layer SE12 are formed in the surrounding area SA, the sealing layer SE12 covers the divided stacked film FL2 with the partition 8. Similarly, when the stacked film FL3 and the sealing layer SE13 are formed in the surrounding area SA, the sealing layer SE13 covers the divided stacked film FL3 with the partition 8. This suppresses undesirable stripping of the stacked film FL2 and the sealing layer SE12 and the stacked film FL3 and the sealing layer SE13.

This configuration can improve yields in the manufacturing of the display device DSP.

FIG. 12 and FIG. 13 explain the effect of the area along the edge portion 12E of the organic insulating layer 12. The same effect is achievable in the dam portions DM4, DM5, and DM6 shown in FIG. 7 as well. That is, the partition 7 overlaps the dam portions DM4, DM5, and DM6. Thus, when the stacked films and the sealing layers are formed on these dam portions, undesirable stripping of the stacked films and the sealing layers can be suppressed.

In addition, the organic insulating layer 12 and the inorganic insulating layer 113 are covered with the inorganic insulating layer 5 as described with reference to FIG. 10. Thus, the inorganic insulating layer 113 is protected by the inorganic insulating layer 5 in the dry etching process after the formation of the inorganic insulating layer 5. This configuration suppresses undesirable scraping of the inorganic insulating layers 113 and 112. This configuration further prevents exposure of the wiring portion ML1 or breakage of the wiring portion ML1 caused by scraping of the inorganic insulating layers 113 and 112 is prevented.

Furthermore, the sealing layer SE2 covers the partition 8 as described with reference to FIG. 10. This mitigates irregularities caused by the partition 8. Thus, coating defects of the resist in the vicinity of the partition 8 is suppressed in the patterning of the metal layer for the formation of the detection electrode DT. Further, the partition 8 is protected by the sealing layer SE2 in the etching process of the metal layer. Further, the sealing layer SE2 covers the inorganic insulating layer 5. Thus, undesirable scraping of the inorganic insulating layers 5, 113, and 112 is suppressed in the area where the organic insulating layer 12 is not provided.

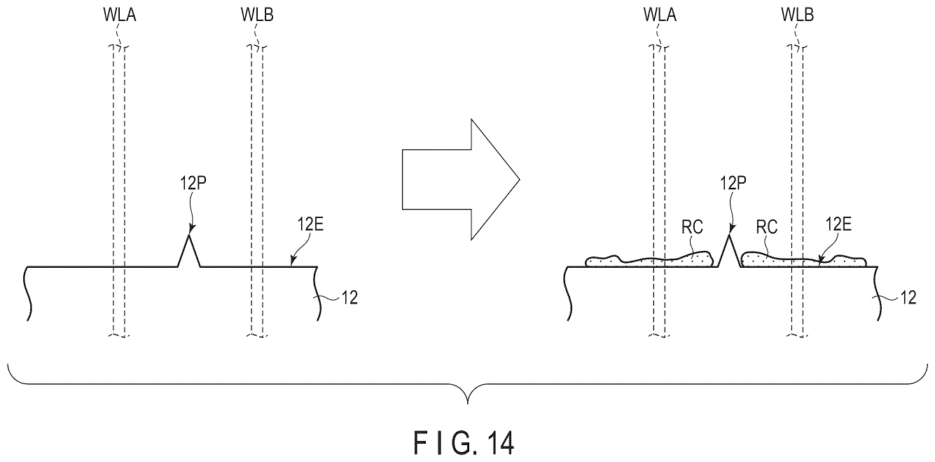

FIG. 14 is a diagram for explaining another effect of the embodiment.

As shown in the left side of the figure, the edge portion 12E of the organic insulating layer 12 has the protrusion 12P between wires WLA and WLB.

As shown in the right side of the figure, when a conductive material RC remains along the edge portion 12E in the manufacturing process after the formation of the organic insulating layer 12, the conductive material RC is divided by the protrusion 12P.

For example, the following assumes cases where the conductive material RC is a conductive material in the formation of the lower electrodes LE1, LE2, and LE3. When the protrusion 12P is not provided, the conductive material RC may extend continuously along the edge portion 12E. In this case, the remaining conductive material RC has the greater planar size and is electrically floating. Thus, electrostatic discharge (ESD) easily occurs between the wires WLA and WLB. This may potentially cause significant damage to the surrounding area of the conductive material RC.

The conductive material RC is divided by the protrusion 12P. This suppresses the conductive material RC increasing its planar size and thus suppresses the electrostatic discharge.

Even if the wires WLA and WLB are exposed, short circuits between them via the conductive material RC are suppressed.

The above descries cases where the conductive material RC forms the lower electrode. However, the same effects can be achieved even if the conductive material RC forms other conductive layers such as the detection electrode DT.

In the embodiment described above, for example, the partition 8 corresponds to the first partition. The lower portion 81 corresponds to the first lower portion. The upper portion 82 corresponds to the first upper portion. The partition 6 corresponds to the second partition. The lower portion 61 corresponds to the second lower portion. The upper portion 62 corresponds to the second upper portion.

The sealing layers SE11, SE12, and SE13 correspond to the first sealing layer. The resin layer RS1 corresponds to the first resin layer. The sealing layer SE2 corresponds to the second sealing layer. The resin layer RS2 corresponds to the second resin layer.

The dam structure DS1 corresponds to the first dam structure. The dam structure DS2 corresponds to the second dam structure.

The first organic layer 114 corresponds to the first layer of each of the organic insulating layers and the dam portions. The organic insulating layer 12 corresponds to the second layer of each of the organic insulating layers and the dam portions.

The first inorganic insulating layer 111 corresponds to the first inorganic insulating layer. The inorganic insulating layer 112 corresponds to the second inorganic insulating layer. The inorganic insulating layer 113 corresponds to the third inorganic insulating layer. The inorganic insulating layer 5 corresponds to the fourth inorganic insulating layer.

In the wire WL, the wiring portion ML1 corresponds to the first wiring portion, the wiring portion ML2 corresponds to the second wiring portion, the wire WLA corresponds to the first wire, and the wire WLB corresponds to the second wire.

As explained above, the present embodiment can provide a display device and a mother substrate that can improve yields and suppress decrease in reliability.

All of the display devices and mother substrates that can be implemented by a person of ordinary skill in the art through arbitrary design changes to the display device and mother substrate described in the embodiments come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is

1. A display device, comprising:
a substrate;
an organic insulating layer formed across a display area for displaying images and a surrounding area located outside the display area;
an inorganic insulating layer provided across the display area and the surrounding area and covering the organic insulating layer;
a lower electrode provided on the organic insulating layer and having a peripheral portion covered with the inorganic insulating layer in the display area;
an organic layer provided on the lower electrode and including a light emitting layer;
an upper electrode provided on the organic layer; and
a first partition provided on the inorganic insulating layer, extending along an edge portion of the organic insulating layer in plan view, and overlapping the edge portion in the surrounding area.

2. The display device of claim 1, wherein
the surrounding area has a cutting line of a panel portion including the display area, and
the cutting line is located between the display area and the first partition.

3. The display device of claim 1, wherein
the first partition overlaps the edge portion facing the display area of the organic insulating layer.

4. The display device of claim 1, wherein
the first partition comprises:
a first lower portion provided on the inorganic insulating layer; and
a first upper portion provided on the first lower portion, and
the first upper portion includes:
one end portion protruding relative to one side surface of the first lower portion in an area overlapping the organic insulating layer; and
other end portion protruding relative to other side surface of the first lower portion in an area where the organic insulating layer is not provided.

5. The display device of claim 1, further comprising:
a second partition provided on the inorganic insulating layer and surrounding the lower electrode, the organic layer, and the upper electrode in plan view in the display area, wherein
the second partition includes:
a second lower portion provided on the inorganic insulating layer, formed of a conductive material, and contacting the upper electrode; and
a second upper portion provided on the second lower portion and having an end portion protruding relative to a side surface of the second lower portion.

6. The display device of claim 5, further comprising:
a cap layer provided on the upper electrode;
a first sealing layer formed of an inorganic insulating material, provided on the cap layer, contacting the second partition, and having an end portion on the second partition;
a first resin layer provided on the first sealing layer; and
a second sealing layer formed of an inorganic insulating material and provided on the first resin layer, wherein
the second sealing layer covers the first partition in the surrounding area.

7. The display device of claim 1, further comprising:
a plurality of wires intersecting the edge portion in plan view, wherein
the edge portion has a protrusion protruding toward the display area between adjacent wires.

8. The display device of claim 7, wherein
the first partition overlaps the protrusion in plan view.

9. The display device of claim 7, further comprising:
a terminal portion provided in the surrounding area and electrically connected to one of the plurality of wires, wherein
the surrounding area has a cutting line of a panel portion including the display area, and
the cutting line is located between the terminal portion and the first portion.

10. The display device of claim 9, further comprising:
a first dam structure provided between the cutting line and the display area and surrounding the display area; and
a second dam structure surrounding the first dam structure, wherein
the second dam structure intersects the cutting line and is coupled to the first dam structure, and
a coupling portion of the first dam structure and the second dam structure is provided between the terminal portion and the display area.

11. A display device, comprising:
a substrate;
a first inorganic insulating layer formed across a display area for displaying images and a surrounding area located outside the display area;
a first wiring portion provided on the first inorganic insulating layer in the surrounding area;
a second inorganic insulating layer covering the first wiring portion;
a second wiring portion provided on the second inorganic insulating layer and electrically connected to the first wiring portion;
a third inorganic insulating layer covering the second wiring portion;
an organic insulating layer provided on the third inorganic insulating layer and having an edge portion directly above the first wiring portion;
an inorganic insulating layer covering the organic insulating layer and covering the third inorganic insulating layer in an area where the organic insulating layer is not provided; and
a first partition provided on the inorganic insulating layer and overlapping the edge portion in the surrounding area.

12. The display device of claim 11, further comprising:
a dam portion surrounding the display area, wherein
each of the organic insulating layer and the dam portion has a first layer provided on the third inorganic insulating layer and a second layer covering the first layer, and
the second layer is covered with the inorganic insulating layer.

13. A display device, comprising:
a substrate;
an organic insulating layer formed across a display area for displaying images and a surrounding area located outside the display area;
an inorganic insulating layer provided across the display area and the surrounding area and covering the organic insulating layer;
a first partition provided on the inorganic insulating layer in the surrounding area, wherein the organic insulating layer has an edge portion facing the display area,
the edge portion includes a protrusion protruding toward the display area, and
the first partition overlaps the edge portion including the protrusion in plan view.

14. The display device of claim 13, further comprising:
a plurality of wires intersecting the edge portion in plan view, wherein
the protrusion is located between adjacent wires.

15. The display device of claim 11, wherein
the first partition comprises:
a first lower portion including a bottom layer provided on the inorganic insulating layer and a stem layer provided on the bottom layer; and
a first upper portion provided on the stem layer, and
each of the bottom layer and the first upper portion includes:
one end portion protruding relative to one side surface of the stem layer in an area overlapping the organic insulating layer; and
other end portion protruding relative to other side surface of the stem layer in an area where the organic insulating layer is not provided.

16. The display device of claim 13, wherein
the first partition comprises:
a first lower portion including a bottom layer provided on the inorganic insulating layer and a stem layer provided on the bottom layer; and
a first upper portion provided on the stem layer, and
each of the bottom layer and the first upper portion includes:
one end portion protruding relative to one side surface of the stem layer in an area overlapping the organic insulating layer; and
other end portion protruding relative to other side surface of the stem layer in an area where the organic insulating layer is not provided.

17. The display device of claim 11, further comprising:
a display element provided in the display area;
a second partition surrounding the display element;
a first sealing layer formed of an inorganic insulating material, overlapping the display element, contacting the second partition, and having an end portion on the second partition;
a first resin layer provided on the first sealing layer; and
a second sealing layer formed of an inorganic insulating material and provided on the first resin layer, wherein
the second sealing layer covers the first partition in the surrounding area.

18. The display device of claim 13, further comprising:
a display element provided in the display area;
a second partition surrounding the display element;
a first sealing layer formed of an inorganic insulating material, overlapping the display element, contacting the second partition, and having an end portion on the second partition;
a first resin layer provided on the first sealing layer; and
a second sealing layer formed of an inorganic insulating material and provided on the first resin layer, wherein
the second sealing layer covers the first partition in the surrounding area.
